(19) United States
(12) Patent Application Publication
(10) Pub. No.: US 2025/0132246 A1
(43) Pub. Date: Apr. 24, 2025

(54) SEMICONDUCTOR STRUCTURES WITH BACKSIDE POWER DELIVERY NETWORK

(71) Applicant: Taiwan Semiconductor Manufacturing Company, Ltd., Hsin-Chu (TW)

(72) Inventors: Yi Ling Liu, Hsinchu City (TW); Tsung-Chieh Hsiao, Changhua County (TW); Liang-Wei Wang, Hsinchu City (TW); Dian-Hau Chen, Hsinchu (TW)

(21) Appl. No.: 18/491,605

(22) Filed: Oct. 20, 2023

(51) Int. Cl. H01L 23/522; H01L 21/768; H01L 23/00; H01L 23/48; H01L 27/088; H01L 29/06; H01L 29/40; H01L 29/417; H01L 29/423; H01L 29/66; H01L 29/775; H01L 29/786

(52) U.S. Cl. CPC H01L 23/5226; H01L 21/76802; H01L 21/76843; H01L 21/76877; H01L 23/481; H01L 24/03; H01L 24/11; H10D 30/014; H10D 30/43; H10D 30/6735; H10D 30/6757; H10D 62/121; H10D 64/01; H10D 64/254; H10D 84/83; H01L 2224/03; H01L 2224/11

(57) ABSTRACT

A semiconductor structure and a method of forming the same are provided. In an embodiment, a method includes receiving a workpiece comprising a first transistor and a second transistor formed over a first side of a substrate, forming a first multi-layer interconnect (MLI) structure over the first side of the substrate, wherein the first MLI structure comprising a first plurality of metal lines and a first plurality of vias, after the forming of the first MLI structure, forming a source/drain contact directly under a source/drain feature of the first transistor, and forming a second MLI structure under the source/drain contact and under a second side of the substrate, the second side being opposite the first side, wherein the MLI structure comprises a second plurality of metal lines and a second via, a thickness of the second via is greater than a thickness of one of the first plurality of vias.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. For example, as integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

As the dimensions of the multi-gate devices shrink, packing all contact features on one side of a substrate is becoming more and more challenging. To case the packing density, routing features may be partially moved to a backside of the substrate. Such routing features may include backside super power Rails (SPRs) and/or backside contacts. While existing backside super power rails (SPRs) may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for forming a semiconductor structure having a backside power delivery network (PDN), according to one or more aspects of the present disclosure.

FIGS. 2, 3, 4, 5, 6, 7, 8, 9, 10, 11, 12, 13, 14, 15, 16, 17, 19, 20, 21, and 22 illustrate fragmentary cross-sectional views of a workpiece during various fabrication stages in the method of FIG. 1, according to one or more aspects of the present disclosure.

FIG. 18 illustrates fragmentary top views of features of the workpiece taken along line A-A and line B-B shown in FIG. 17, according to one or more aspects of the present disclosure.

FIGS. 23 and 24 illustrate fragmentary cross-sectional views of alternative structures of the workpiece, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

IC manufacturing process flow may be typically divided into three categories: front-end-of-line (FEOL) processes, middle-end-of-line (MEOL) processes, and back-end-of-line (BEOL) processes. FEOL processes generally encompasses processes related to fabricating IC devices, such as transistors. For example, FEOL processes may include forming isolation features, gate structures, and source/drain features. Source/drain feature(s) may refer to a source or a drain, individually or collectively dependent upon the context. MEOL processes generally encompasses processes related to fabricating contacts to conductive features of the IC devices, such as gate vias to the gate structures and/or source/drain contacts to the source/drain features. BEOL processes generally encompasses processes related to fabricating a multi-layer interconnect structure that interconnects IC features fabricated by FEOL and MEOL process, thereby enabling operation of the IC devices. Features fabricated by FEOL processes may be referred to as FEOL features. Features fabricated by MEOL processes may be referred to as MEOL features. Features fabricated by BEOL processes may be referred to as BEOL features.

In some existing chip structures, MEOL features (e.g., source/drain contacts, contact vias of transistors) are formed over a front side of the substrate and connect source/drain features of the transistors to BEOL features (e.g., a multi-layer interconnect structure) that are also disposed over the front side of the substrate. As the dimensions of IC devices shrink, the close proximity among the source/drain contacts and gate vias may reduce process windows for forming these conductive features and may increase parasitic capacitance among them. To alleviate these concerns, some IC chips (e.g., super power rail (SPR) chips) may implement a backside source/drain contact through the substrate to come in contact with a source/drain feature, and a power rail is formed on the back side of the substrate to be in contact with the backside source/drain contact. Since the implementation of SPR structures cases the crowding of contacts, SPR chips entail a modern solution for performance boost on power delivery network (PDN) for advanced technology nodes. PDN is a structure that delivers power and ground voltages from conductive pad locations to the various components (e.g., transistors) of the chips. However, conductive features (e.g., backside metal lines and backside conductive vias) in the PDN may be formed to have small dimensions and may include materials (e.g., titanium nitride) having high resistivity, leading to a large current-resistance (IR) drop during power delivery. When the voltage at a transistor drops, it become slower and this may disadvantageously impact the circuit timing. For some SPR chips that include devices to be implemented in high power applications, such large IR drop may change timing or even directly cause functional failures. Large IR drops may also force the use of voltage supplies with higher voltage potentials, which may be more difficult to implement or more expensive. Large IR drops may also make devices more susceptible to voltage supply noise.

The present disclosure provides semiconductor structures with reduced current-resistance (IR) drop and methods of forming the same. In an embodiment, after forming MEOL features and BEOL features over a front side of the transistors and after forming backside source/drain contacts under the transistors, a power delivery network is formed under the backside source/drain contacts to electrically couple to the transistors. A portion of the power delivery network includes a through dielectric via disposed vertically between two metal lines and is configured to provide power delivery path for devices to be implemented in high power applications. Compared with power delivery networks that are formed of a backside multi-layer interconnect structure and are free of the through dielectric via, the power delivery network of the present disclosure has a reduced parasitic resistance and thus provides a reduced IR drop during power delivery.

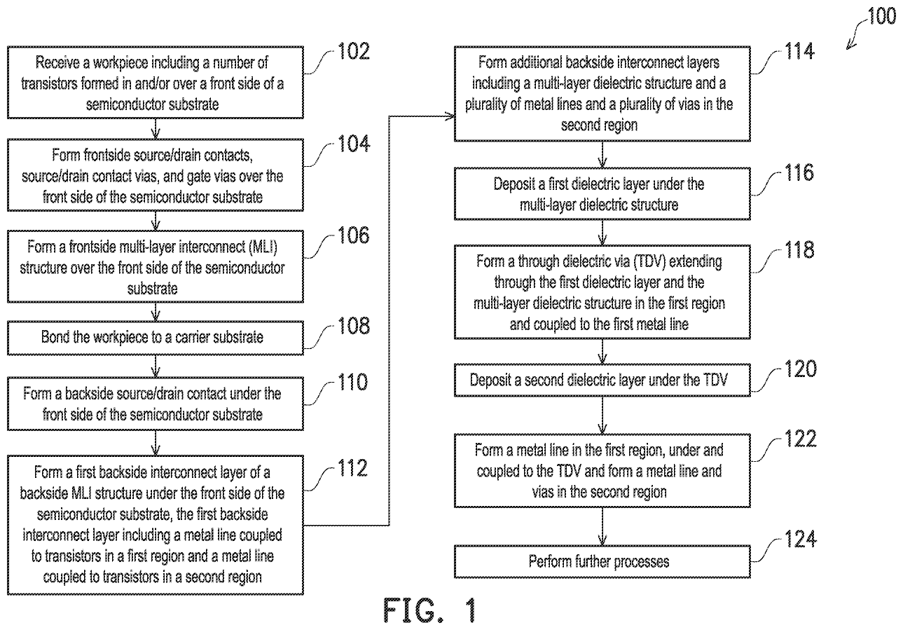

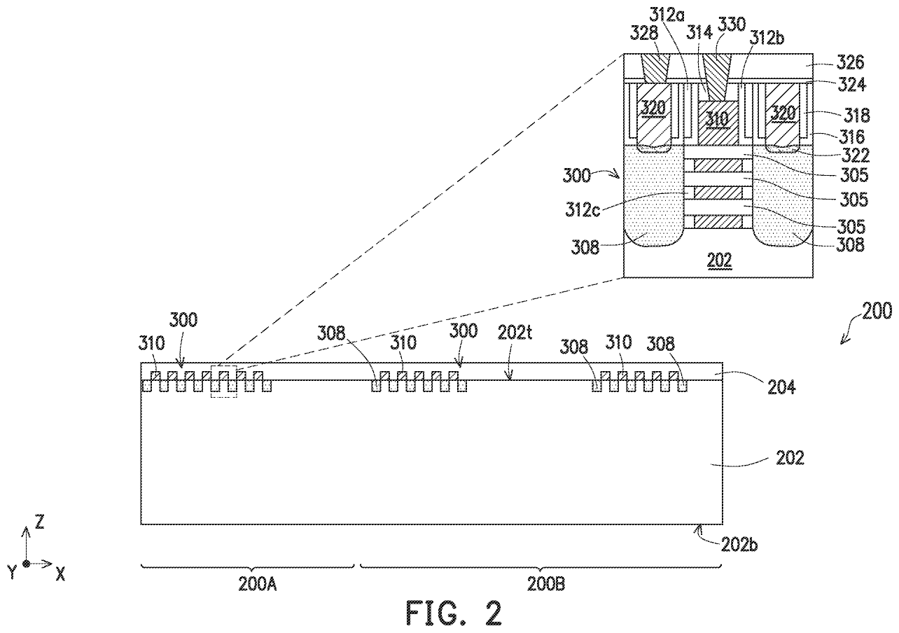

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-24, which are fragmentary cross-sectional views or fragmentary top views of a workpiece 200 at different stages of fabrication according to embodiments of method 100. Method 100 is merely an example and is not intended to limit the present disclosure to what is explicitly illustrated therein. Additional steps may be provided before, during, and/or after the method 100, and some steps described can be replaced, eliminated, or moved around for additional embodiments of the method. Not all steps are described herein in detail for reasons of simplicity. Because the workpiece 200 will be fabricated into a semiconductor structure 200 upon conclusion of the fabrication processes, the workpiece 200 may be referred to as the semiconductor structure 200 as the context requires. For avoidance of doubts, the X, Y and Z directions in FIGS. 2-24 are perpendicular to one another and are used consistently throughout FIGS. 2-24. Throughout the present disclosure, like reference numerals denote like features unless otherwise excepted.

Referring to FIGS. 1 and 2, method 100 includes a block 102 where a workpiece 200 is received. The workpiece 200 includes a substrate 202 having a top surface 202t and a bottom surface 202b opposite the top surface 202t. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof, or other suitable materials. In some alternative embodiments, the substrate 202 may be a semiconductor-on-insulator substrate, such as a silicon-on-insulator (SOI) substrate, a silicon germanium-on-insulator (SGOI) substrate, or a germanium-on-insulator (GOI) substrate. The substrate 202 may include multiple doped regions (e.g., N-type doped wells, P-type doped wells). Each of the N-type doped wells may be doped with an N-type dopant, such as phosphorus, arsenic, other N-type dopants, or combinations thereof. Each P-type doped wells may be doped with a P-type dopant, such as boron, indium, other P-type dopants, or combinations thereof. Each of the various doped regions may be formed by performing an ion implantation process, a diffusion process, other suitable doping processes, or combinations thereof.

The workpiece 200 also includes a number of transistors 300 formed in and/or over the top surface 202t of the substrate 202. In the present embodiments, a number of transistors 300 are formed in a first region 200A of the workpiece 200, and a number of transistors 300 are formed in a second region 200B of the workpiece 200. Upon completion of the fabrication process, the first region 200A of the workpiece 200 may be implemented in high power applications (e.g., CPU, GPU), and the second region 200B of the workpiece 200 may be implemented in low power applications.

In the present embodiments, each of the transistors 300 is a GAA transistor. An exemplary structure of the transistor 300 is enlarged and shown in FIG. 2. The transistor 300 includes a number of channel layers 305 stacked vertically along the Z-axis. Each of the channel layers 305 may include Si, Ge, SiC, SiGe, GeSn, SiGeSn, SiGeCSn, other suitable semiconductor materials, or combinations thereof. In the present embodiments, each of the channel layers 305 includes Si in the form of a nanosheet, a nanowire (e.g., a nanowire having a hexagonal cross-section), a nanorod (e.g., a nanorod having a square or round cross-section), or other suitable configurations. In some embodiments, the transistor 300 includes two to ten channel layers 305. Of course, the present disclosure is not limited to such configurations and the number of channel layers 305 may be tuned according to design requirements for the semiconductor structure 200.

The transistor 300 also includes source/drain features 308 coupled to the channel layers 305. The transistor 300 may be an N-type transistor or a P-type transistor, and the source/drain features 308 may be N-type source/drain features or P-type source/drain features, accordingly. Exemplary N-type source/drain features may include silicon, phosphorus-doped silicon, arsenic-doped silicon, antimony-doped silicon, or other suitable material and may be in-situ doped during the epitaxial process by introducing an N-type dopant, such as phosphorus, arsenic, or antimony, or ex-situ doped using a junction implant process. Exemplary P-type source/drain features may include germanium, gallium-doped silicon germanium, boron-doped silicon germanium, or other suitable material and may be in-situ doped during the epitaxial process by introducing a P-type dopant, such as boron or gallium, or ex-situ doped using a junction implant process. In some embodiments, each of the source/drain features 308 may be a multi-layer structure that includes an undoped semiconductor layer, a lightly doped semiconductor layer, and a heavily doped semiconductor layer.

The transistor 300 also includes a gate structure 310 wrapping around and over each of the channel layers 305. The gate structure 310 includes at least a high-K gate dielectric layer (not separately labeled) and a metal gate electrode (not separately labeled) over the high-K gate dielectric layer. The high-K gate dielectric layer may include silicon oxynitride, aluminum silicon oxide, a high-K dielectric material such as hafnium oxide, zirconium oxide, lanthanum oxide, titanium oxide, yttrium oxide, strontium titanate, other suitable dielectric materials, or combinations thereof. Though not depicted, each metal gate electrode may include a bulk conductive layer. The bulk conductive layer may include Cu, W, Ru, Co, Al, Ti, Ta, other suitable metals, or combinations thereof. In some examples, each gate structure may include one or more work function metal layer of the same conductivity type or of different conductivity types. Examples of the work function metal layers may include TiN, TaN, Ru, Mo, Al, WN, ZrSi₂, MoSi₂, TaSi₂, NiSi₂, Ti, Ag, TaAl, TaAlC, TiAlN, TaC, TaCN, TaSiN, Mn, Zr, other suitable work function materials, or combinations thereof. Additional material layers may also be included in each gate structure, such as an interfacial layer, a barrier layer, a capping layer, other suitable materials layers, or combinations thereof.

The transistor 300 also includes top spacers 312a and 312b and inner spacers 312c disposed on sidewalls of the gate structure 310, where the top spacers 312a and 312b are disposed over the topmost channel layer 305 and the inner spacers 312c are disposed in the space between two vertically stacked channel layers 305. In some embodiments, the top spacers 312a and 312b may include silicon oxide, silicon oxycarbide, silicon carbonitride, silicon nitride, zirconium oxide, aluminum oxide, or other suitable dielectric materials. The inner spacers 312c may include silicon oxide, silicon nitride, silicon oxycarbide, silicon oxycarbonitride, silicon carbonitride, metal nitride, or a suitable dielectric material. In some embodiments, the transistor 300 also includes a dielectric capping layer 314 formed on the gate structure 310. The top spacers 312a and 312b also extend along the sidewall surface of the dielectric capping layer 314. In some other embodiments, the dielectric capping layer 314 may be formed on and in direct contact with both the gate structure 310 and the top spacers 312a and 312b.

The transistor 300 also includes a contact etch stop layer (CESL) 316 and an interlayer dielectric (ILD) layer 318 disposed over the source/drain features 308 and adjacent to the sidewalls of the top spacers 312a and 312b. The CESL 316 may include silicon nitride, silicon oxynitride, and/or other materials known in the art and may be formed by atomic layer deposition (ALD) process, plasma-enhanced chemical vapor deposition (PECVD) process and/or other suitable deposition or oxidation processes. The ILD layer 318 may be deposited by a PECVD process or other suitable deposition technique over the source/drain features 308 after the deposition of the CESL 316. The ILD layer 318 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Still referring to FIGS. 1 and 2, method 100 includes a block 104 where source/drain contacts, source/drain contact vias, and gate vias are formed over the top surface 202t (or front side) of the substrate 202. In an exemplary process, a patterned mask layer (not shown) is formed over the transistor 300, and while using the patterned mask layer as an etch mask, an etching process may be performed to remove portions of the ILD layer 318 and the CESL 316 to form source/drain contact openings exposing the source/drain features 308. Silicide layers 322 and source/drain contacts 320 are then formed in the source/drain contact openings. The source/drain contact 320 is electrically couple to the source/drain feature 308 via the silicide layer 322. Since the source/drain contacts 320 are formed over the front side of the substrate 202, the source/drain contacts 320 may be referred to as frontside source/drain contacts 320. The frontside source/drain contacts 320 may include any suitable conductive material, such as Cu, W, Ru, Co, Al, Ti, Ta, other suitable metals, or combinations thereof. Each source/drain contacts 320 may further include a barrier layer comprising any suitable material, such as Ti, Ta, TiN, TaN, other suitable materials, or combinations thereof. The silicide layer 322 may include nickel silicide, titanium silicide, cobalt silicide, other suitable silicides, or combinations thereof.

After forming the frontside source/drain contacts 320, an etch stop layer 324 and a dielectric layer 326 are formed over the transistor 300. The compositions and formations of the etch stop layer 324 and the dielectric layer 326 may be similar to those of the CESL 316 and the ILD layer 318, respectively, and repeated description is omitted for reason of simplicity. Source/drain contact vias (e.g., source/drain contact via 328) are formed over the frontside source/drain contacts 320, and gate vias (e.g., gate via 330) are formed over the gate structures 310 of the transistors 300. The compositions and formations of the source/drain contact vias (e.g., source/drain contact via 328) and gate vias (e.g., gate via 330) may be similar to those of the frontside source/drain contacts 320. In the present disclosure, the frontside MEOL features (e.g., the frontside source/drain contacts 320, gate vias 330, source/drain contact vias 328) and associated dielectric layers (e.g., the dielectric layer 326) may be collectively referred to as a contact layer 204. It is understood that the contact layer 204 includes multiple gate vias 330 electrically coupled to corresponding gate structures 310, multiple frontside source/drain contacts 320 electrically coupled to corresponding source/drain features 308, and multiple source/drain contact vias 328 electrically coupled to corresponding frontside source/drain contacts 320.

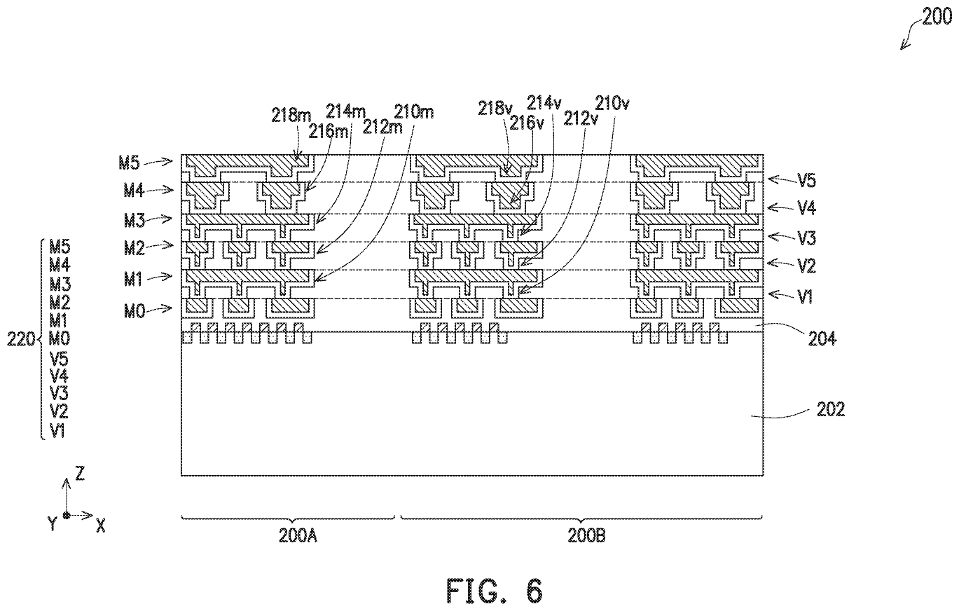

Referring to FIGS. 1 and 3-6, method 100 includes a block 106 where a multi-layer interconnect (MLI) structure 220 (shown in FIG. 6) is formed over the front side of the substrate 202. At its completion, the multi-layer interconnect structure 220 may include a plurality of interconnect layers that include interconnection elements such as metal lines, as well as conductive vias that vertically interconnect different metal lines from different interconnect layers.

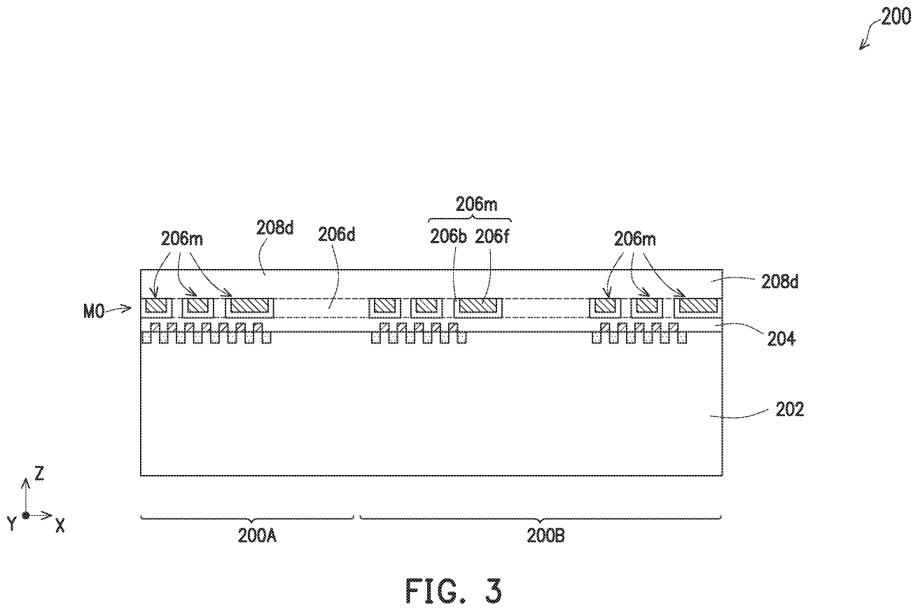

In embodiments represented by FIG. 3, after forming the contact layer 204, a Metal-0 interconnect layer M0 (as a bottommost interconnect layer of the multi-layer interconnect structure 220) is formed on the contact layer 204. The Metal-0 interconnect layer M0 may be referred to as the M0 layer. The formation of the M0 layer includes forming a dielectric layer 206d over the front side of the substrate 202, including over the transistors 300. The dielectric layer 206d may be formed using a deposition process, such as chemical vapor deposition (CVD), physical vapor deposition (PVD), atomic layer deposition (ALD), or other suable deposition processes. In some embodiments, the dielectric layer 206d may include a dielectric material, such as silicon oxide or silicon nitride. In other embodiments, the dielectric layer 206d may include a polymer material. In some embodiments, the dielectric layer 206d is a dual-layer structure and includes an interlayer dielectric layer formed on an etch stop layer.

One or more etching processes may be performed to form a number of trenches in the dielectric layer 206d, and one or more deposition processes may be performed to fill the trenches with conductive materials. The deposition processes may include CVD, PVD, ALD, or combinations thereof. For example, a first deposition process may be performed to conformally deposit a barrier layer 206b over the workpiece 200, including in the trenches. The barrier layer 206b may include Ti, Ta, TiN, or TaN. A second deposition process may be then performed to form a metal fill layer 206f over the barrier layer 206b to substantially fill remaining portions of the trenches. A planarization process, such as chemical mechanical polishing (CMP) process, may be then performed to remove excess portions of the barrier layer 206b and metal fill layer 206f outside the of the trenches and over the dielectric layer 206d, thereby forming metal lines 206m in the dielectric layer 206d. In an embodiment, the metal fill layer 206f includes copper. In other embodiments, the metal fill layer 206f may include cobalt, ruthenium, tungsten, aluminum, or combinations thereof.

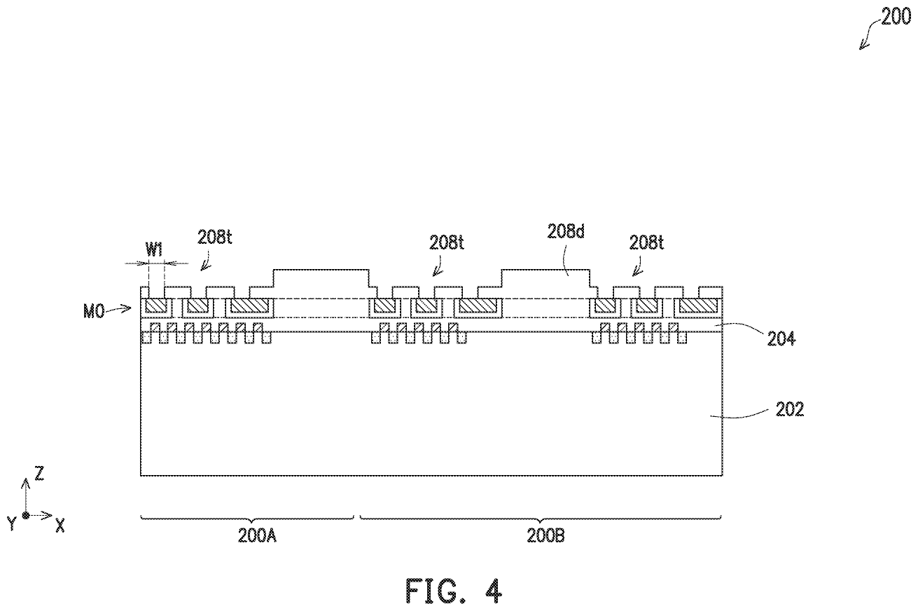

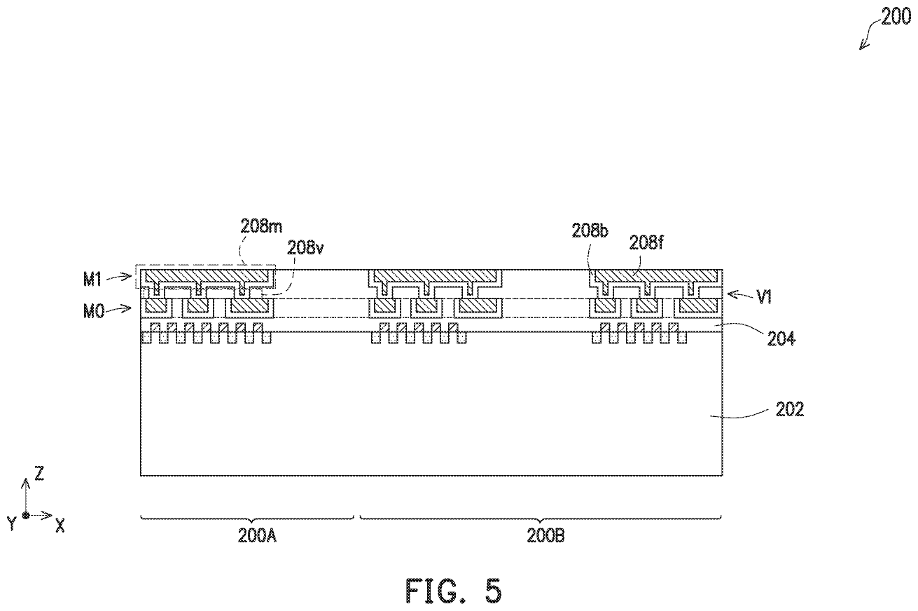

After forming the M0 layer, referring now to FIGS. 3-5, a Metal-1 interconnect layer M1 of the multi-layer interconnect structure 220 is formed over the M0 layer. The Metal-1 interconnect layer M1 may be referred to as the M1 layer. The M1 layer includes metal lines 208m embedded in a dielectric layer 208d. In some embodiments, the dielectric layer 208d is a dual-layer structure and includes an interlayer dielectric layer formed on an etch stop layer. The workpiece 200 also includes a Via-1 interconnect layer V1 formed between the M0 layer and the M1 layer. The Via-1 interconnect layer V1 may be referred to as a V1 layer. The V1 layer includes a number of conductive vias 208v embedded in the dielectric layer 208d and configured to electrically connect metal lines 206m of the M0 layer with metal lines 208m of the M1 layer. A dual damascene process may be used to form the conductive vias 208v in the V1 layer and the metal lines 208m in the M1 layer. The conductive via 208v has a width W1 (shown in FIG. 4) along the X direction. In an example process, as depicted in FIG. 3, one or more deposition processes (e.g., CVD, PVD, ALD) may be performed to form the dielectric layer 208d on the M0 layer, including on the top surfaces of the metal lines 206m. Thereafter, as represented by FIG. 4, one or more etching processes may be performed to the workpiece 200 to etch a number of trenches 208t in the dielectric layer 208d. As depicted in FIG. 4, at least one of the trenches 208t include a lower portion and an upper portion, and the upper portion spans a width greater than that of the lower portion. Reference is now made to FIG. 5. A barrier layer 208b is conformally deposited over the workpiece 200, including in the trenches 208t, and a metal fill layer 208f is then deposited over the barrier layer 208b and in the trenches 208t. A planarization process may be applied to the workpiece 200 to remove excess portions of the barrier layer 208b and the metal fill layer 208f to form metal lines 208m in the M1 layer and conductive vias 208v in the V1 layer. The compositions and formations of the barrier layer 208b and the metal fill layer 208f may be similar to those of the barrier layer 206b and the metal fill layer 206f, and repeated descriptions are omitted for reason of simplicity. In the present disclosure, the metal line 208m and the conductive via 208v thereunder are formed by a dual damascene process, and they are portions of an integral conducive feature. The part of the integral conductive feature that is formed in the lower portion of the trench 208t is referred to as the conductive via 208v, the part of the integral conductive feature that is formed in the upper portion of the trench 208t is referred to as the metal line 208m.

After forming the M1 layer and the V1 layer, as illustrated in FIG. 6, more interconnect layers, such as Metal-2 interconnect layer M2, Via-2 interconnect layer V2, Metal-3 interconnect layer M3, Via-3 interconnect layer V3, Metal-4 interconnect layer M4, Via-4 interconnect layer V4, Metal-5 interconnect layer M5, and Via-5 interconnect layer V5 are formed over the M0 layer to finish the fabrication of the multi-layer interconnect structure 220. Metal-2 interconnect layer M2, Metal-3 interconnect layer M3, Metal-4 interconnect layer M4, and Metal-5 interconnect layer M5 may be referred to as the M2 layer, the M3 layer, the M4 layer and the M5 layer, respectively. Via-2 interconnect layer V2, Via-3 interconnect layer V3, Via-4 interconnect layer V4, and Via-5 interconnect layer V5 may be referred to as the V2 layer, the V3 layer, the V4 layer, and the V5 layer, respectively. The M2 layer and V2 layer, the M3 layer and V3 layer, the M4 layer and V4 layer, the M5 layer and V5 layer each may be formed in a way similar to that of the M1 layer and V1 layer. For example, M2 layer and V2 layer, the M3 layer and V3 layer, the M4 layer and V4 layer, the M5 layer and V5 layer each may be performed by forming a dielectric layer, and then performing a dual damascene process to form metal lines and conductive vias in the dielectric layer. For reason of simplicity, those dielectric layers of the multi-layer interconnect structure 220 may be individually or collectively referred to as the dielectric layer(s) 208d. Metal lines formed at the M2 layer, M3 layer, M4 layer and M5 layer may be referred to as metal lines 210m, metal lines 212m, metal lines 214m, metal lines 216m, and metal lines 218m, respectively. Conductive vias formed at the V2 layer, V3 layer, V4 layer and V5 layer may be referred to as conductive vias 210v, conductive vias 212v, conductive vias 214v, conductive vias 216v, and conductive vias 218v, respectively. It is understood that the number of interconnect layers of the multi-layer interconnect structure 220 shown in FIG. 6 is just an example, the multi-layer interconnect structure 220 may include any suitable number of interconnect layers. Because the multi-layer interconnect structure 220 is formed over the front side of the transistors 300, the multi-layer interconnect structure 220 may also be referred to as a frontside interconnect structure 220.

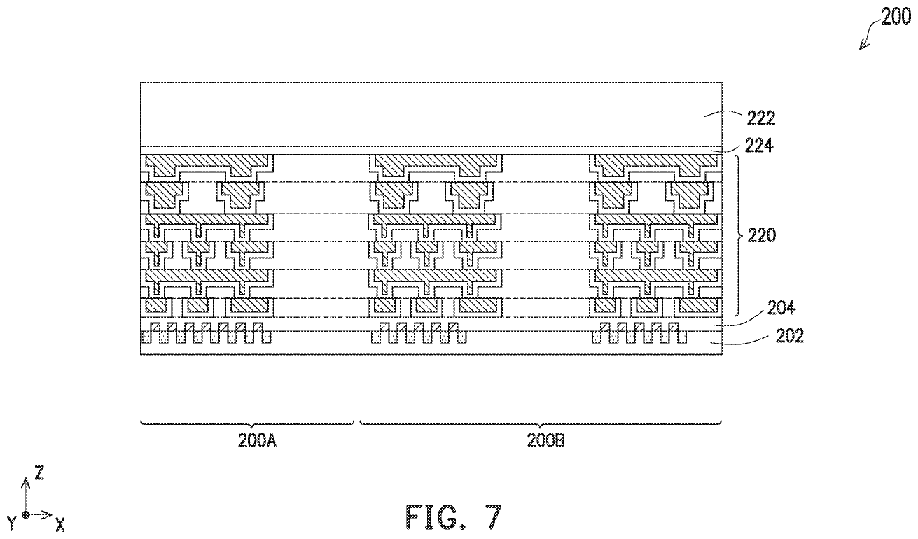

Referring to FIGS. 1 and 7, method 100 includes a block 108 where the workpiece 200 is bonded to a carrier substrate 222. In some embodiments, the carrier substrate 222 may be bonded to the workpiece 200 by fusion bonding, by use of an adhesion layer, or a combination thereof. In some instances, the carrier substrate 222 may include semiconductor materials (such as silicon), sapphire, glass, polymeric materials, or other suitable materials. In the present embodiments, the carrier substrate 222 is bonded to the frontside interconnect structure 220 by use of an adhesion layer 224. Once the carrier substrate 222 is bonded to the frontside interconnect structure 220 of the workpiece 200, the workpiece 200 may be flipped over (not shown) and planarized from the bottom surface 202b of the substrate 202 to reduce a thickness of the substrate 202 to facilitate the formation of features under the transistors 300. All processes that are implemented to form features under the back side of the transistors 300 are performed when the workpiece 200 is flipped over. However, for reason of simplicity, all positional relationships throughout the present disclosure are described in a way that does not consider the flip over of the substrate 202.

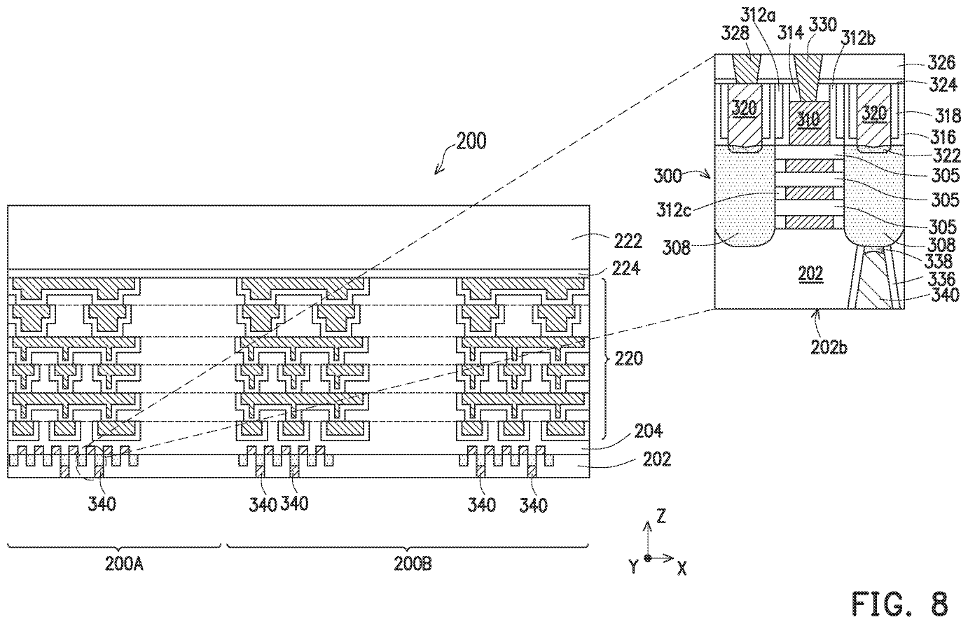

Referring to FIGS. 1 and 8, method 100 includes a block 110 where one or more source/drain contacts 340 are formed under the bottom of the transistors 300. For case of description, a portion of the workpiece 200 including the source/drain contact 340 is enlarged. In an exemplary process, after the substrate 202 is thinned down, a patterned mask layer (not shown) may be formed under the bottom surface 202b of the substrate 202 to cover portions of the substrate 202. While using the patterned mask layer as an etch mask, an etching process may be performed to remove portions of the substrate 202 not covered by the patterned mask layer to form source/drain contact openings extending through the substrate 202 from its back side to expose a bottom surface of at least one or more source/drain features 308 of the transistors 300. The source/drain contact openings formed under the back side of the transistors may be referred to as backside source/drain contact openings, and the source/drain contacts 340 that will be formed in the backside source/drain contact openings may be referred to as backside source/drain contacts 340.

After forming the backside source/drain contact opening, a dielectric barrier layer 336 may be conformally deposited and is then etched back to only cover sidewall of the backside source/drain contact opening while exposing the source/drain feature 308. In some embodiments, the dielectric barrier layer 336 may include silicon nitride or other suitable materials. The dielectric barrier layer 336 extends along the substrate 202 and disposed directly under the source/drain feature 308.

Operations at block 110 also includes forming a silicide layer 338 in the backside source/drain contact opening to reduce a contact resistance between the source/drain feature 308 and the to-be-formed backside source/drain contact 340. The silicide layer 338 may include titanium silicide, tantalum silicide, nickel silicide, cobalt silicide, or tungsten silicide. After the formation of the silicide layer 338, the backside source/drain contact 340 may be formed in the backside source/drain contact opening. The backside source/drain contact 340 may include aluminum, rhodium, ruthenium, copper, iridium, or tungsten. The backside source/drain contact 340 is electrically coupled to the source/drain feature by way of the silicide layer 338. In other words, the silicide layer 338 is sandwiched between the source/drain feature 308 and the backside source/drain contact 340.

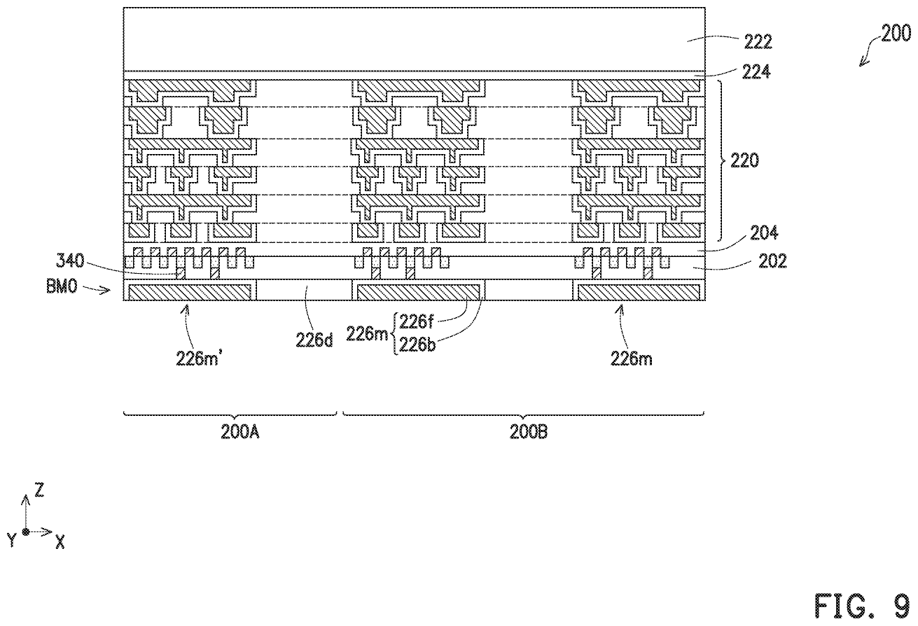

Referring to FIGS. 1 and 9, method 100 includes a block 112 where a backside Metal-0 interconnect layer BM0 is formed under the bottom surface 202b of the substrate 202. In embodiments represented by FIG. 9, after forming the backside source/drain contacts 340, the backside Metal-0 interconnect layer BM0 (as a topmost interconnect layer of a backside multi-layer interconnect (MLI) structure 260) is formed under the backside source/drain contacts 340. The backside Metal-0 interconnect layer BM0 may be referred to as the BM0 layer. The BM0 layer is a portion of the backside MLI structure 260 and thus is also a portion of a power delivery network (PDN) 270. The formation of the BM0 layer includes forming a dielectric layer 226d under the back side of the substrate 202. The dielectric layer 226d may be formed using a deposition process, such as chemical vapor deposition (CVD), physical vapor deposition (PVD), atomic layer deposition (ALD), or other suitable materials. In some embodiments, the dielectric layer 226d may include a dielectric material, such as silicon oxide or silicon nitride. In other embodiments, the dielectric layer 226d may include a polymer material. One or more etching processes may then be performed to form a number of trenches in the dielectric layer to expose bottom surfaces of the backside source/drain contacts 340. After that, one or more deposition processes may be performed to fill the trenches with conductive materials. The deposition processes may include CVD, PVD, ALD, or combinations thereof. For example, a first deposition process may be performed to conformally deposit a barrier layer 226b in the trenches. The barrier layer 226b may include Ti, Ta, TiN, or TaN. A second deposition process may be then performed to form a metal fill layer 226f to substantially fill remaining parts of the trenches. A planarization process, such as chemical mechanical polishing (CMP) process, may be then performed to remove excess portions of the barrier layer 226b and metal fill layer 226f outside of the trenches, thereby forming metal lines 226m in the dielectric layer 226d. In an embodiment, the metal fill layer 226f includes copper. In other embodiments, the metal fill layer 226f may include cobalt, ruthenium, tungsten, aluminum, or combinations thereof. Each of the metal lines 226m is in direct contact with one or more backside source/drain contacts 340. It is noted that, the backside source/drain contacts 340 are formed in both the first region 200A and the second region 200B. For ease of description, the metal lines 226m formed in the second region 200B may be referred to as metal lines 226m, and metal line(s) 226m formed in the first region 200A may be referred to as metal line(s) 226m′.

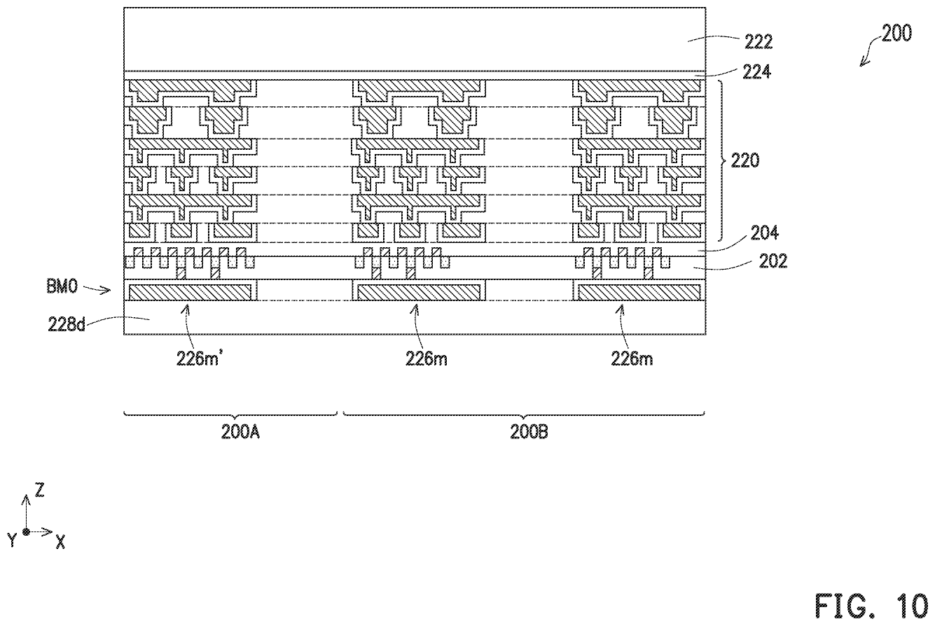

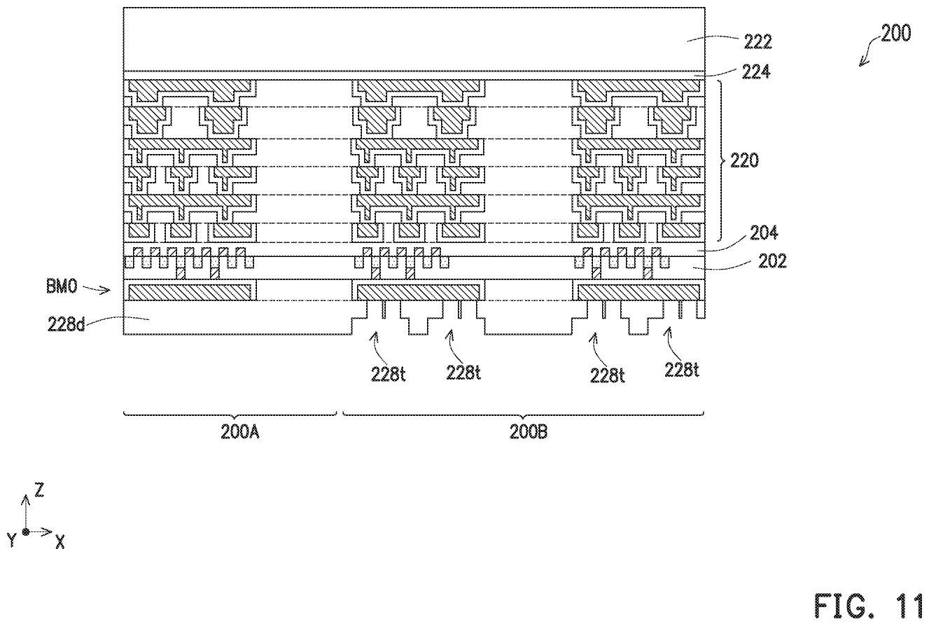

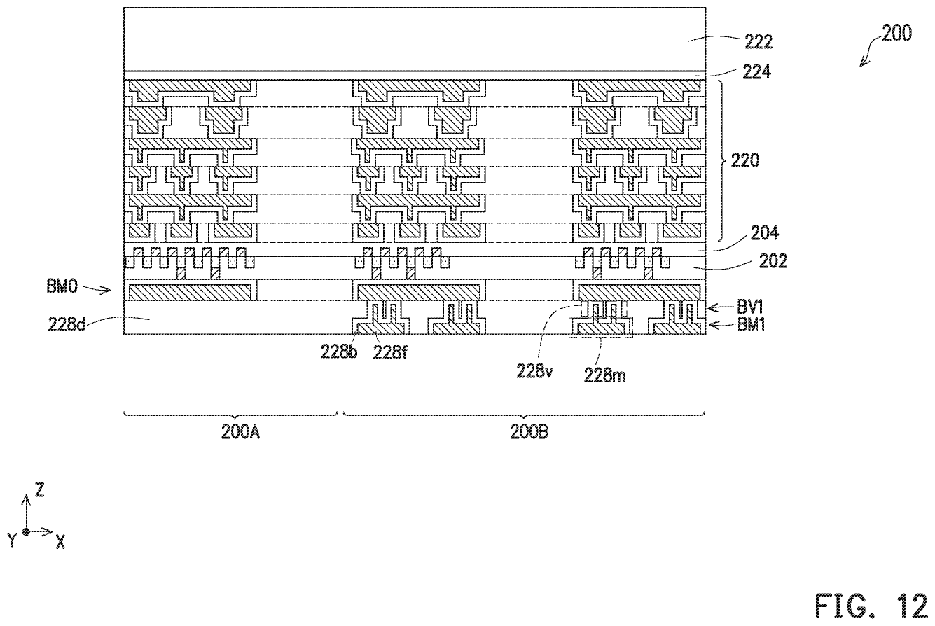

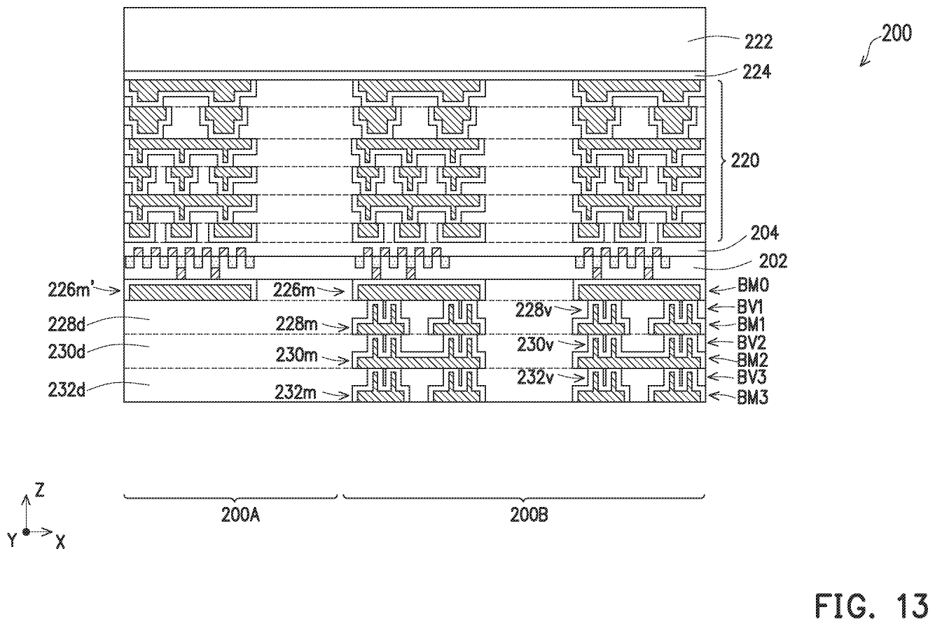

Referring to FIGS. 1 and 13, method 100 includes a block 114 where additional backside interconnect layers are formed under the BM0 layer. After forming the BM0 layer, referring now to FIGS. 10-12, a backside Metal-1 interconnect layer BM1 of the backside MLI structure 260 is formed under the BM0 layer. The backside Metal-1 interconnect layer BM1 may be referred to as the BM1 layer. The BM1 layer includes metal lines 228m embedded in a dielectric layer 228d and in the second region 200B. The workpiece 200 also includes a backside Via-1 interconnect layer BV1 formed between the BM0 layer and the BM1 layer. The backside Via-1 interconnect layer BV1 may be referred to as a BV1 layer. The BV1 layer includes a number of backside conductive vias 228v embedded in the dielectric layer 228d and in the second region 200B and configured to electrically couple metal lines 226m of the BM0 layer to metal lines 228m of the BM1 layer. A dual damascene process may be used to form the conductive vias 228v in the BV1 layer and the metal lines 228m in the BM1 layer. In an example process, as depicted in FIG. 10, one or more deposition processes (e.g., CVD, PVD, ALD, etc.) may be performed to form the dielectric layer 228d under the BM0 layer, including under the bottom surfaces of the metal lines 226m. Thereafter, as represented by FIG. 11, one or more etching processes may be performed to the workpiece 200 to etch a number of trenches 228t in the dielectric layer 228d. In the present embodiments, the trenches 228t are formed in the second region 200B while not being formed in the first region 200A. As depicted in FIG. 11, at least one of the trenches 228t include a lower portion and an upper portion, and the upper portion spans a width less than that of the lower portion. Reference is then made to FIG. 12. A barrier layer 228b is conformally deposited under the workpiece 200, including in the trenches 228t, and a metal fill layer 228f is then deposited to fill the trenches 228t. A planarization process may be applied to the workpiece 200 to remove excess portions of the barrier layer 228b and the metal fill layer 228f to form metal lines 228m in the BM1 layer and conductive vias 228v in the BV1 layer. The compositions and formations of the barrier layer 228b and the metal fill layer 228f may be similar to those of the barrier layer 206b and the metal fill layer 206f, and repeated descriptions are omitted for reason of simplicity. In the present disclosure, the metal line 228m and the conductive via 228v are formed by a dual damascene process, and they are portions of an integral conducive feature. The part of the integral conductive feature that is formed in the upper portion of the trench 228t is referred to as the conductive via 228v, the part of the integral conductive feature that is formed in the lower portion of the trench 228t is referred to as the metal line 228m. It is noted that the metal line 228m and conductive via 228v are formed in the second region 200B while not being formed in the first region 200A.

Still referring to FIGS. 1 and 13, operations in block 114 also include forming more backside interconnect layers of the backside MLI structure 260 under the substrate 202. After forming the BM1 layer and the BV1 layer, in embodiments represented by FIG. 13, more backside interconnect layers, such as backside Via-2 interconnect layer BV2, backside Metal-2 interconnect layer BM2, backside Via-3 interconnect layer BV3, and backside Metal-3 interconnect layer BM3 are formed under the BM0 layer. The backside Metal-2 interconnect layer BM2 and backside Metal-3 interconnect layer BM3 may be referred to as BM2 layer and BM3 layer, respectively. The backside Via-2 interconnect layer BV2 and backside Via-3 interconnect layer BV3 may be referred to as BV2 layer and BV3 layer, respectively. The BM2 layer and BV2 layer, the BM3 layer and BV3 layer, each may be formed in a way similar to that of the BM1 layer and BV1 layer. For example, the BM2 layer and BV2 layer may be formed by forming a dielectric layer 230d, and then performing a dual damascene process to form metal lines and conductive vias in the dielectric layer 230d; the BM3 layer and BV3 layer may be formed by forming a dielectric layer 232d, and then performing a dual damascene process to form metal lines and conductive vias in the dielectric layer 232d. Metal lines formed at the BM2 layer and BM3 layer may be referred to as metal lines 230m and metal lines 232m, respectively. Conductive vias formed at the BV2 layer and BV3 layer may be referred to as conductive vias 230v and conductive vias 232v, respectively. The metal lines 230m, 232m and conductive vias 230v, 232v are all formed in the second region 200B while not being formed in the first region 200A. It is understood that the number of interconnect layers of the backside MLI structure 260 shown in FIG. 13 is just an example, the backside MLI structure 260 may include any suitable number of interconnect layers.

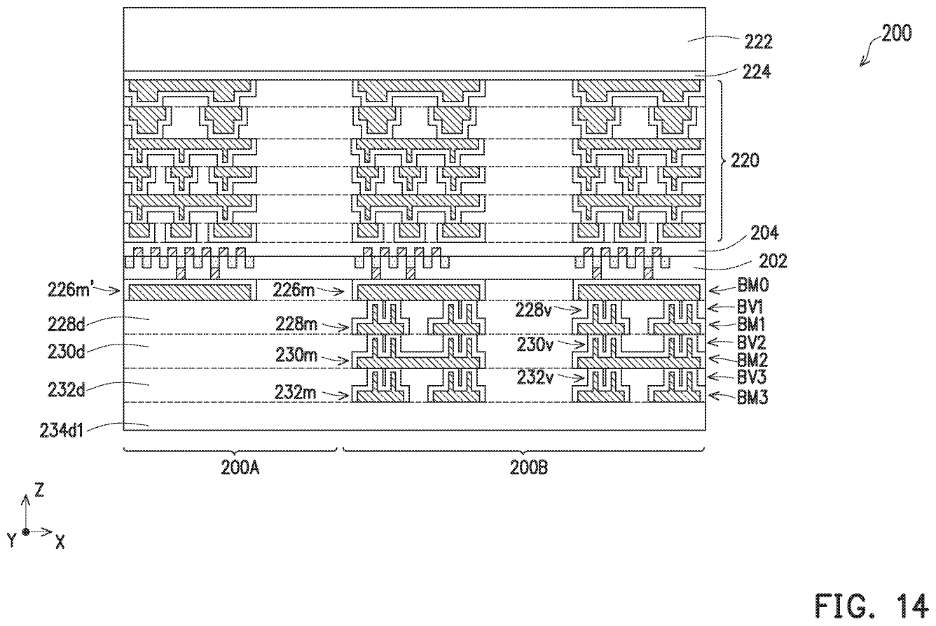

Referring to FIGS. 1 and 14, method 100 includes a block 116 where a first dielectric layer 234d1 is formed under the BM3 layer. The first dielectric layer 234d1 may be formed using a deposition process, such as chemical vapor deposition (CVD), physical vapor deposition (PVD), atomic layer deposition (ALD), or other suitable materials. In some embodiments, the first dielectric layer 234d1 may include a dielectric material, such as silicon oxide or silicon nitride. In other embodiments, the first dielectric layer 234d1 may include a polymer material.

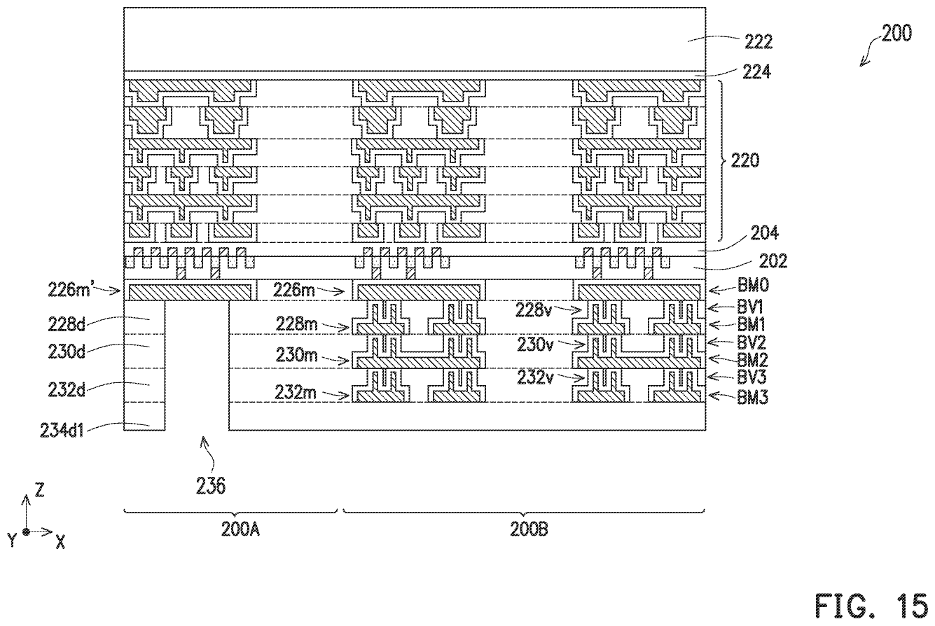

Referring to FIGS. 1 and 15-18, method 100 includes a block 118 where a conductive via 238 is formed in the first region 200A and coupled to the metal line 226m′ in the first region 200A. In an example process, a mask film (e.g., a hard mask layer and/or a photoresist layer) may be formed under the first dielectric layer 234d1 and then patterned to form an opening exposing a portion of the first dielectric layer 234d1 disposed directly under the metal line 226m′ in the first region 200A while covering other features in the first region 200A and the second region 200B. With reference to FIG. 15, while using the patterned mask film (not shown) as an etch mask, an etching process is performed to remove the portions of the dielectric layers 228d, 230d, 232d, and 234d1 exposed by the opening of the patterned mask film to form a trench 236 in the first region 200A. That is, the trench 236 extends through the dielectric layers 228d, 230d, 232d, and 234d1 and exposes at least a portion of a bottom surface of the metal line 226m′ formed in the first region 200A.

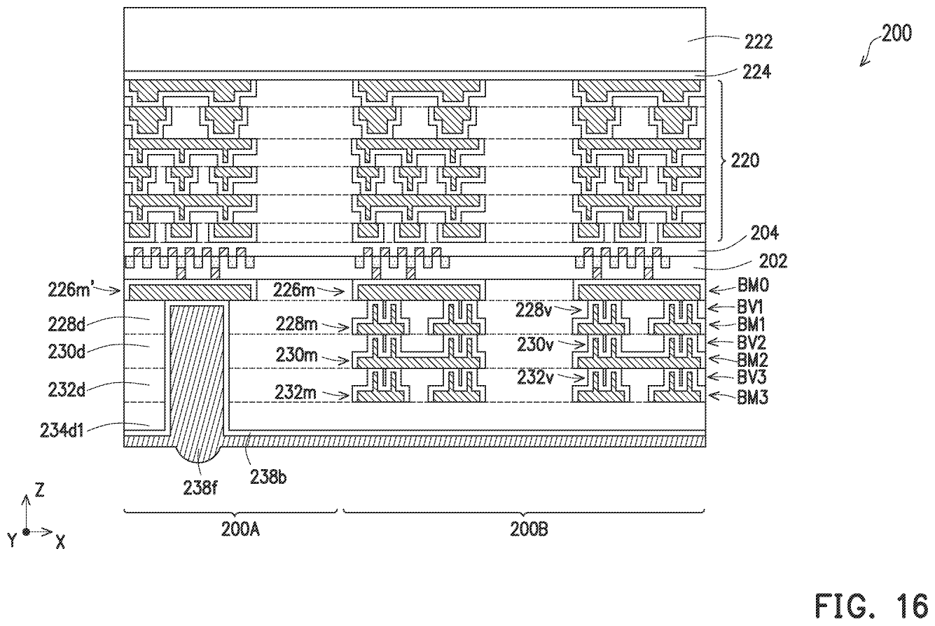

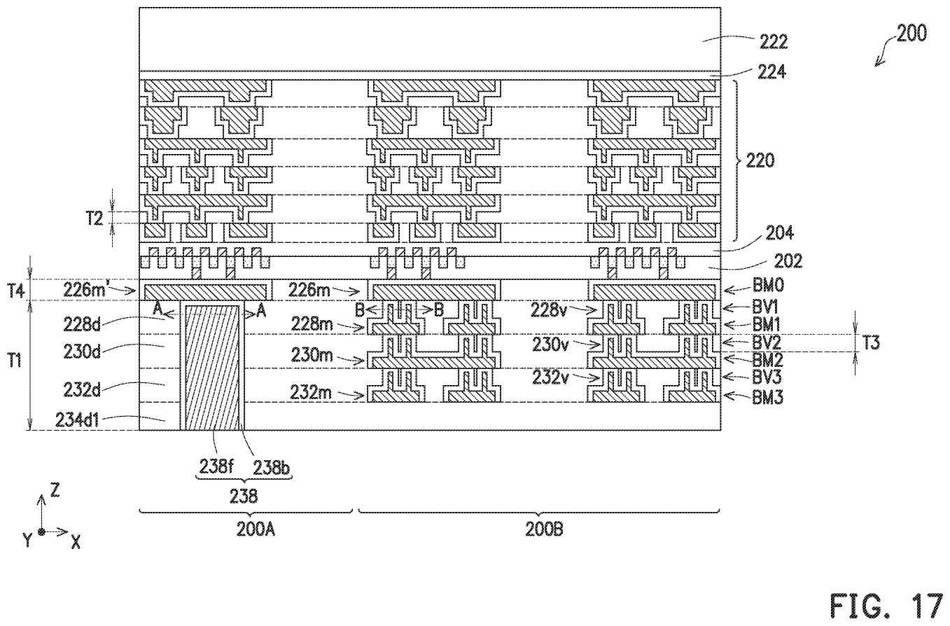

With reference to FIGS. 16-17, after forming the trench 236, the conductive via 238 is formed in the trench 236. Since the conductive via 238 extends through the dielectric layers 228d, 230d, 232d, and 234d, the conductive via 238 may be referred to as a through dielectric via (TDV) 238 or a through oxide via (TOV) 238 if the dielectric layers 228d, 230d, 232d, and 234d are formed of oxide. In an example process, as depicted in FIG. 16, a seed layer (or barrier layer) 238b is conformally deposited to partially fill the trench 236. The seed layer 238b may include titanium nitride (TiN) or other suitable materials. After depositing the seed layer 238b, a metal fill layer 238f is formed to fill a remaining portion of the trench 236. The metal fill layer 238f may include copper, cobalt, ruthenium, tungsten, aluminum, or combinations thereof. In an embodiment, the metal fill layer 238f includes copper. In an embodiment, the copper-based metal fill layer 238f is formed by electrochemical plating. As depicted in FIG. 17, a planarization process may be performed to remove excess portions of the metal fill layer 238f and the seed layer 238b outside of the trench 236, thereby providing the TDV 238 a planar bottom surface. After performing the planarization process, the bottom surface of the TDV 238 in the first region 200A is substantially coplanar with a bottom surface of first dielectric layer 234d1. The TDV 238 has a thickness T1 that is greater than a thickness T2 of any one of the conductive vias in the MLI structure 220. In an embodiment, the thickness T1 is also greater than a thickness T3 of any one of the conductive vias in the MLI structure 260. In some embodiments, the thickness T1 is also greater than a thickness T4 of any of the metal lines (e.g., the metal line 226m′) in the MLI structure 260.

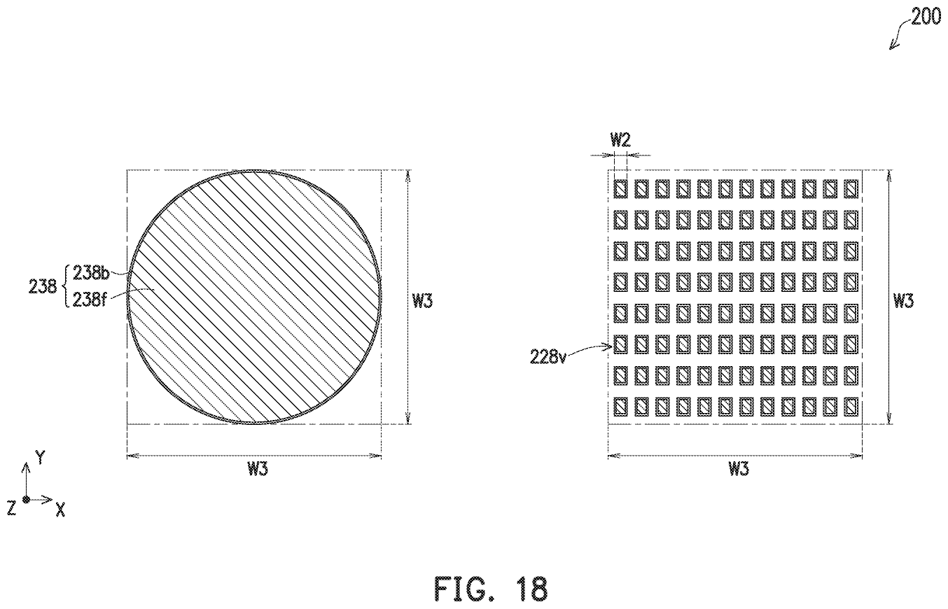

FIG. 18 depicts an exemplary fragmentary top view of the TDV 238 in the first region 200A and an exemplary fragmentary top view of the conductive vias (e.g., conductive vias 228v) in the second region 200B. In the present embodiments, the top view of the TDV 238 is taken along line A-A shown in FIG. 17, and the top view of the conductive vias (e.g., the conductive vias 228v) in the second region 200B is taken along line B-B shown in FIG. 17. In the present embodiment, as shown in FIG. 18, when viewed from top and within a same area (e.g., product of length W3 and width W3), the first region 200A includes only one TDV 238, and the second region 200B includes a number of conductive vias 228v since the TDV 238 spans a width W3 that is greater than a width W2 of each of the conductive vias 228v. That is, a density of conductive features of the second region 200B is greater than a density of conductive features in the first region 200A. In some embodiments, to effectively reduce the IR drop, a ratio of width W3 to the width W2 is great than 10. In some embodiments, a width of one or more of the conducive vias of the MLI structure 220 is substantially equal to the width W1. In this present embodiment, a shape of a top view of the TDV 238 is substantially a round shape, and a shape of a top view of the conductive via 228v is substantially a rectangular shape. It is understood that the shapes of the top views of the TDV 238 and conductive via 228v may include other shapes, such as round, square, and/or rectangle.

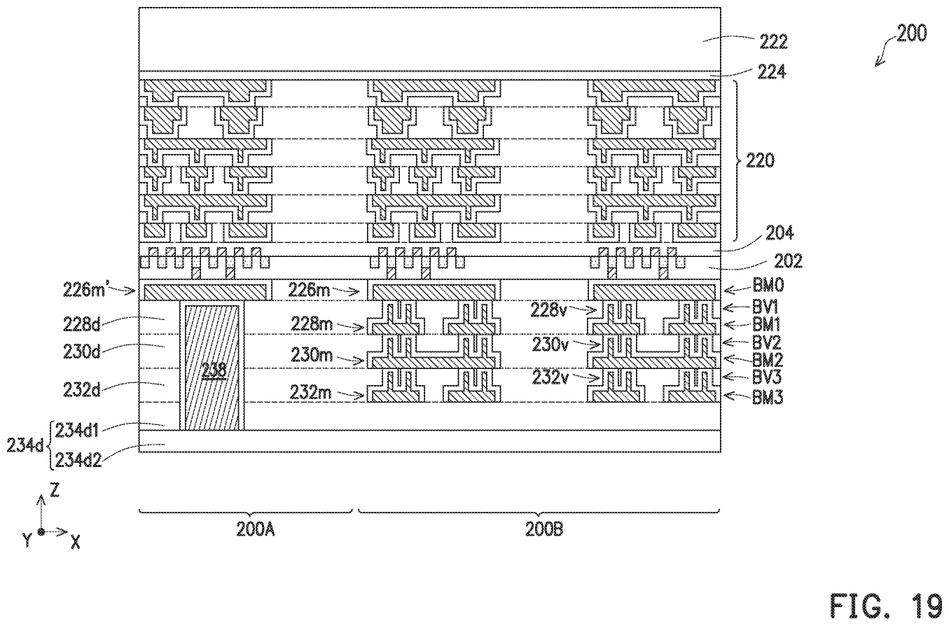

Referring to FIGS. 1 and 19, method 100 includes a block 120 where a second dielectric layer 234d2 is formed under the first dielectric layer 234d1. The formation and composition of the second dielectric layer 234d2 may be similar to those of the first dielectric layer 234d1, and repeated description is omitted for reason of simplicity. The first dielectric layer 234d1 and the second dielectric layer 234d2 may be collectively referred to as a dielectric layer 234d.

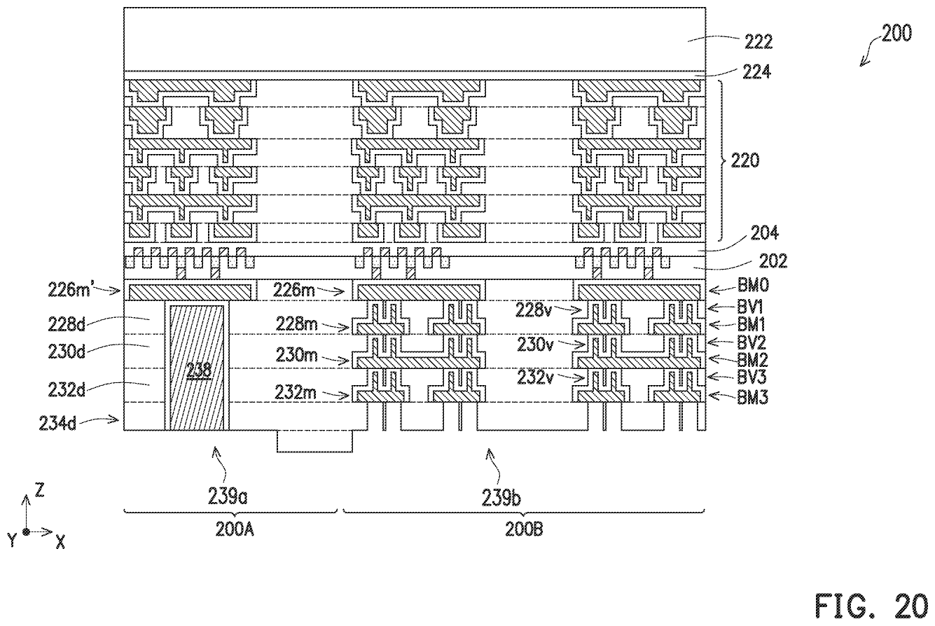

Referring to FIGS. 1 and 20-21, method 100 includes a block 122 where a metal line 242m is formed under the TDV 238 and in the first region 200A, and at least one metal line 234m and conductive vias 234v are formed under the metal lines 232m and in the second region 200B. In the present embodiment, after forming the second dielectric layer 234d2, a trench 239a (shown in FIG. 20) is formed in the first region 200A to expose a bottom surface of the TDV 238, and one or more trenches 239b (shown in FIG. 20) are formed in the second region 200B to expose bottom surfaces of the metal lines 232m. The trench 239a formed in the first region 200A and trenches 239b formed in the second region 200B may be formed simultaneously or in any sequential order. In the present embodiment, the trench 239a extends through the second dielectric layer 234d2 to expose the TDV 238, and the trench 239b extends through both the first dielectric layer 234d1 and the second dielectric layer 234d2 to expose the bottom surfaces of the metal liens 232m. That is, the trench 239a and the trench 239b have different depths.

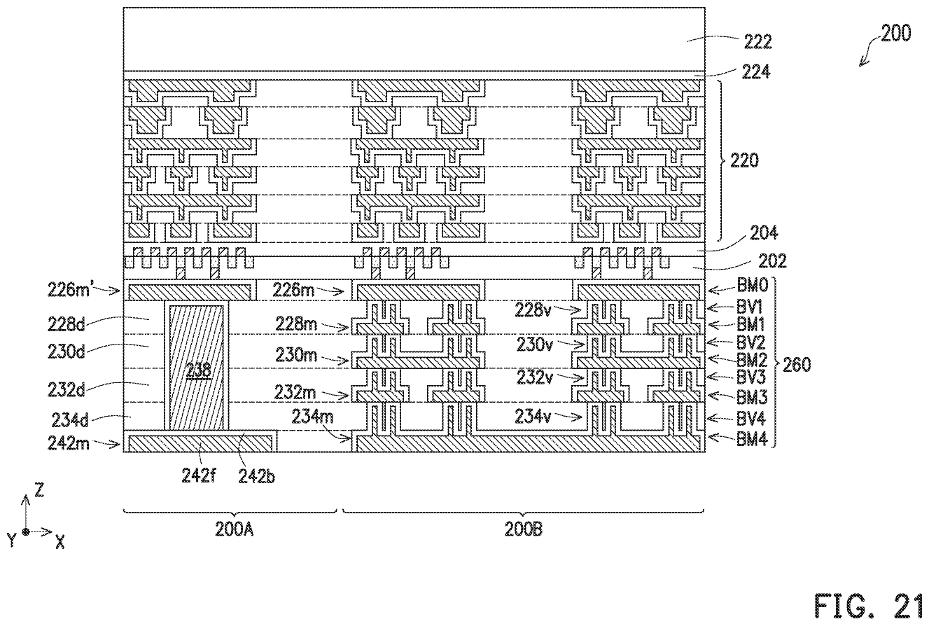

After forming the trenches 239a and 239b, with reference to FIG. 21, the metal line 242m is formed in the trench 239a to directly contact the TDV 238, and the metal line 234m and conductive vias 234v are formed in the trench 239b to directly contact the metal lines 232m. In an example process, a barrier layer 242b is conformally deposited and a metal fill layer 242f is then deposited to fill remaining portions of the trenches 239a and 239b. In an embodiment, the barrier layer 242b may include titanium nitride, and the metal fill layer 242f may include copper. A CMP process may be then performed to remove excess portions of the barrier layer 242b and metal fill layer 242f disposed outside of the trenches 239a and 239b. The bottom surface of the metal line 242m is coplanar with the bottom surface of the metal line 234m in the second region 200B, and the top surface of the metal line 242m may be above, below, or coplanar with the top surface of the metal line 234m in the second region 200B. In an embodiment, a thickness of the metal line 242m is different than a thickness of the metal line 234m. In an embodiment, the metal line 234m and the second dielectric layer 234d2 may be collectively referred to as a backside interconnect layer BM4 (or BM4 layer) of the backside MLI structure 260, and the conductive vias 234v and the first dielectric layer 234d1 may be collectively referred to as a backside interconnect layer BV4 (or BV4 layer) of the backside MLI structure 260.

While the MLI structure 220, the adhesion layer 224, and the carrier substrate 222 are located on the front side of the substrate 202, the power delivery network (PDN) 270 is formed on the back side of the substrate 202. The PDN 270 is a structure that delivers power and ground voltages from conductive pad locations to the various components (e.g., the transistors 300) of the workpiece 200. In the present embodiments, the PDN 270 includes the metal lines and conductive vias of the MLI structure 260 formed in the second region 200B. The PDN 270 also includes the metal line 226m′, the metal line 242m, and the TDV 238 formed in the first region 200A. Electrical connectivity to the PDN 270 (and to the rest of the workpiece 200) may be gained by conductive bumps 252 (e.g., solder balls) that are located on the back side of the PDN 270.

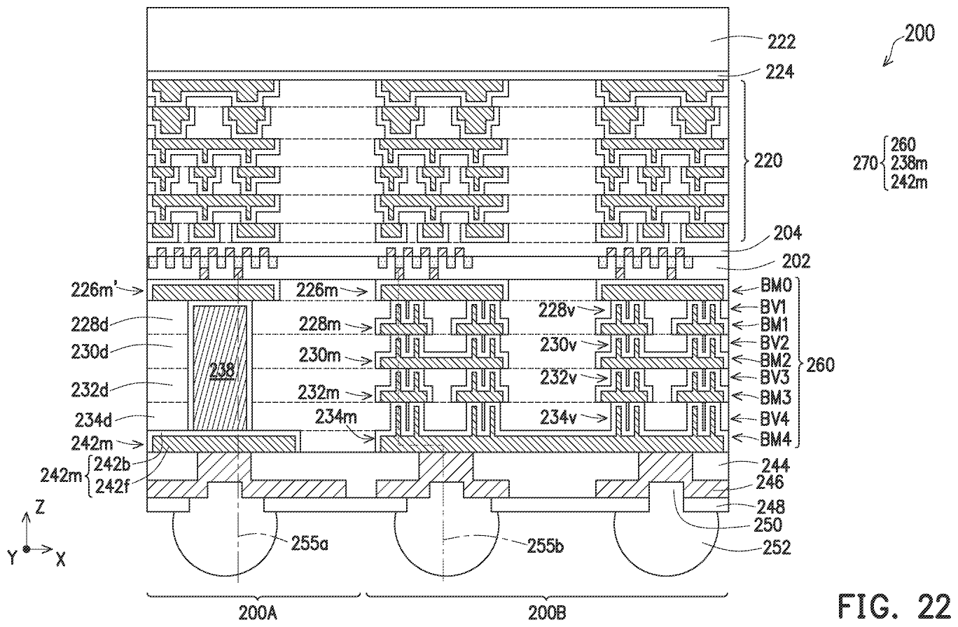

Referring to FIGS. 1 and 22, method 100 includes a block 120 where further processes are performed. Such further processes may include forming a first passivation structure 244 under the metal lines 234m and 242m, forming bonding pads 246 (e.g., aluminum pads) extending through the first passivation structure 244 to electrically couple to the metal lines 234m and 242m. Such further processes may also include forming a second passivation structure 248 under the first passivation structure 244, forming under bump metals (UBMs) 250 extending through the second passivation structure 248 to electrically couple to the bonding pads 246, and forming solder balls 252 under the UBMs 250. The solder balls 252 may be configured to be input/output (I/O) connectors. Such further processes may also include bonding the workpiece 200 to another IC chip or a printed circuit board (PCB).

In the above embodiments, the TDV 238 in the first region 200A is formed after forming the metal lines (e.g., the metal lines 228m, 230m, and 232m) and conducive vias (e.g., the conductive vias 228v, 239v, 232v) in the second region 200B that are laterally adjacent the TDV 238. In some other implementations, the TDV 238 may be formed before forming the metal lines and conducive vias in the second region 200B.

In the present disclosure, compared with a second conductive path (represented by the dashed line 255b) between the backside source/drain contacts 340 and solder balls 252 in the second region 200B that is formed of a number of metal lines (e.g., metal lines 226m, 228m, 230m, 232m, 234m) and a number of conductive vias (e.g., conductive vias 228v, 230v, 232v, 234v) disposed therebetween, a first conductive path (represented by the dashed line 255a) between the backside source/drain contacts 340 and solder balls 252 in the first region 200A includes two metal lines (e.g., metal lines 226m′ and 242m) and the TDV 238. That is, the number of barrier layers in the first conductive path (represented by the dashed line 255a) of the first region 200A is much less than the number of barrier layers in the second conductive path (represented by the dashed line 255b) of the second region 200B. Reducing barrier layers in the conductive path 255a would reduce a parasitic resistance and thus reduce IR drop in the conductive path 255a of the first region 200A. That is, due to the presence of the TDV 238, the IR drop caused by the portion of the PDN 270 in the first region 200A is less than the IR drop caused by the portion of the PDN 270 in the second region 200B.

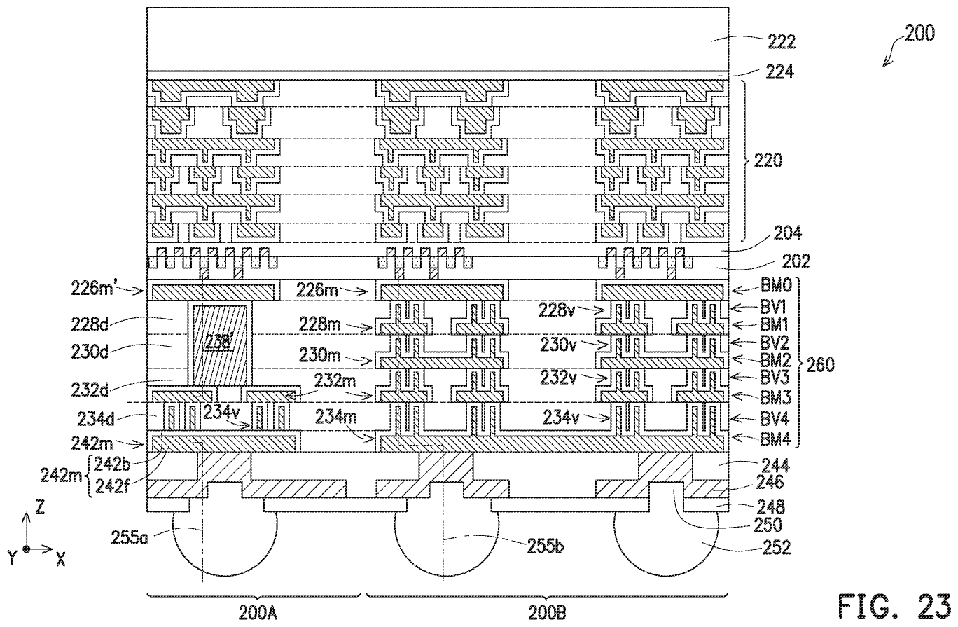

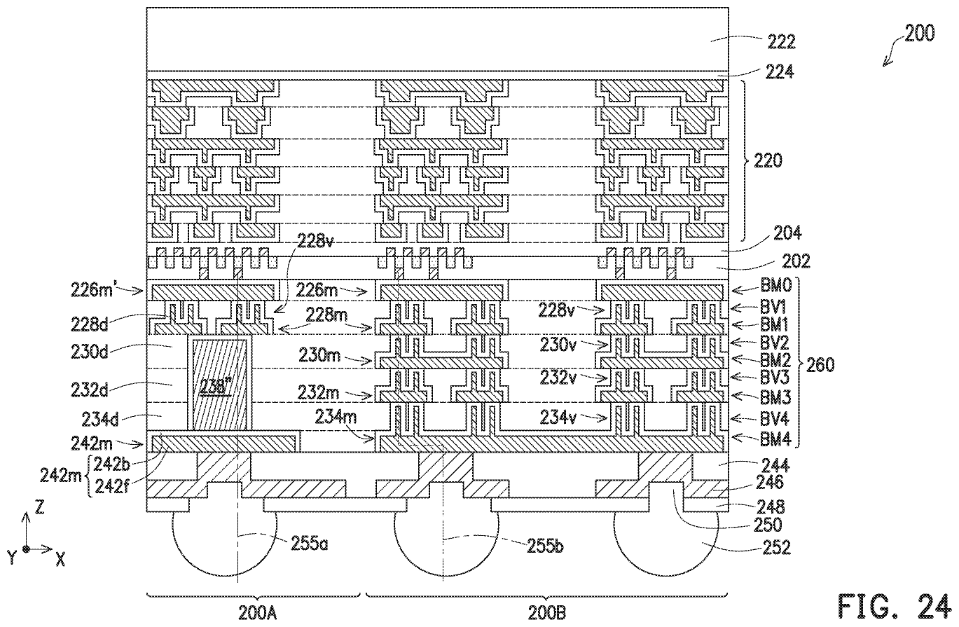

In the above embodiments, compared with the second conductive path (represented by the dashed line 255b), the first conductive path (represented by the dashed line 255a) may be regarded as replacing all the metal lines and conductive vias disposed between the topmost metal line (e.g., the metal line 226m) and bottommost metal line (e.g., the metal line 234m) of the backside MLI structure 260 with the TDV 238. In some other implementations, only portions of those metal lines and conductive vias are replaced by the TDV 238. For example, in embodiments represented by FIG. 23, the first conductive path 255a not only includes TDV 238′, but also includes the metal lines 232m and the conductive vias 234v. The TDV 238′ is in direct contact with the metal line 226m′. In embodiments represented by FIG. 24, the first conductive path 255a not only includes TDV 238″, but also includes the metal lines 228m and the conductive vias 228v. The TDV 238″ is in direct contact with the metal line 242m. The TDV 238′ and the TDV 238″ are similar to the TDV 238, except for the dimensions. The extent at which the IR drop is improved may be flexibly adjusted by configuring the number of metal lines and conductive vias in the first conductive path 255a, as represented by embodiments illustrated in FIGS. 22-24.

In the above embodiments, the metal lines and conductive vias (e.g., conductive vias 228v and metal lines 228m) in the MLI structures 220 and 260 are formed by implanting a dual damascene process. Other processes may also be used to form those metal lines and conductive vias. For example, the metal lines (e.g., metal lines 228m) may be formed after forming the conductive vias (e.g., conductive vias 228v), and the metal fill layer of the metal line is spaced apart from the metal fill layer of the conductive feature by a barrier layer of the metal line.

Embodiments of the present disclosure provide advantages. Methods of the present disclosure provide a power delivery network with reduced IR drop. In an embodiment, the power delivery network includes a first portion having a through dielectric via disposed between a topmost interconnect layer of a MLI structure and a bottommost interconnect layer of the MLI structure. The power delivery network also includes a second portion having a number of metal lines and conductive vias disposed between the topmost interconnect layer and the bottommost interconnect layer of the MLI structure. Forming the through dielectric via reduces a parasitic resistance of the power delivery network and thus reduces IR drop during power delivery.

The present disclosure provides for many different embodiments. Semiconductor structures and methods of fabrication thereof are disclosed herein. In one exemplary aspect, the present disclosure is directed to a method. The method includes receiving a workpiece comprising a first transistor and a second transistor formed over a first side of a substrate, forming a first multi-layer interconnect structure over the first side of the substrate, wherein the first multi-layer interconnect structure comprising a first plurality of metal lines and a first plurality of vias, after the forming of the first multi-layer interconnect structure, forming a source/drain contact directly under a source/drain feature of the first transistor, and forming a second multi-layer interconnect structure under the source/drain contact and under a second side of the substrate, the second side being opposite the first side, wherein the second multi-layer interconnect structure comprises a second plurality of metal lines and a second via, wherein a thickness of the second via is greater than a thickness of a via of the first plurality of vias.

In some embodiments, the via of the first plurality of vias spans a first width, the second via spans a second width, a ratio of the second width to the first width is greater than 10. In some embodiments, the second via is disposed vertically between and in direct contact with two metal lines of the second plurality of metal lines, and one of the two metal lines of the second plurality of metal lines is in direct contact with the source/drain contact. In some embodiments, the forming of the second multi-layer interconnect structure may include depositing a first dielectric layer under the second side of the substrate, forming a first trench in the first dielectric layer to expose a bottom surface of the source/drain contact, forming one of the second plurality of metal lines in the first trench, depositing a second dielectric layer under the first dielectric layer, depositing a third dielectric layer under the second dielectric layer, forming a second trench extending through the second and third dielectric layers, the second trench exposing a portion of the one of the second plurality of metal lines, forming the second via in the second trench, and forming another one of the second plurality of metal lines under the second via. In some embodiments, the forming of the second via may include forming a barrier layer in the second trench, forming a conductive material to fill a remaining part of the second trench, and performing a planarization process to remove portions of the barrier layer and conductive material disposed under the third dielectric layer. The method may also include, after the forming of the second multi-layer interconnect structure, forming a conductive pad under and in direct contact with the second via, and forming a solder bump under the conductive pad. In some embodiments, the second transistor may include a plurality of nanostructures disposed over the substrate, a gate structure wrapping around and over each of the plurality of nanostructures, and a source feature and a drain feature coupled to the plurality of nanostructures. In some embodiments, the forming of the source/drain contact may include reducing a thickness of the substrate, forming an opening extending through the substrate to expose a bottom surface of the source/drain feature, forming a dielectric liner extending along sidewall surface of the opening, forming a silicide layer in the opening and in direct contact with the source/drain feature, and depositing a conductive material in the opening. The method may also include, before the forming of the first multi-layer interconnect structure, forming source/drain contacts and gate vias over the first side of the substrate. In some embodiments, the thickness of the second via may be greater than a thickness of a metal line of the second plurality of metal lines.

In another exemplary aspect, the present disclosure is directed to a method. The method includes receiving a workpiece comprising a first plurality of transistors in a first region and a second plurality of transistors in a second region over a substrate, and forming a power delivery network under the substrate to provide power signals to the first plurality of transistors and the second plurality of transistors, wherein the power delivery network comprises a first portion having a first number of conductive features electrically coupled to the first plurality of transistors and a second portion having a second number of conductive features electrically coupled to the second plurality of transistors, wherein the first number is less than the second number.

In some embodiments, the method may also include, before the forming of the power delivery network, forming gate vias over and electrically coupled to gate structures of the first plurality of transistors and the second plurality of transistors, forming source/drain contacts over and electrically coupled to source/drain features of the first plurality of transistors and the second plurality of transistors by way of silicide layers, and forming an interconnect structure over the workpiece, the interconnect structure comprising metal lines and vias embedded in dielectric layers and over the gate vias and the source/drain contacts. The method may also include before the forming of the power delivery network, thinning down a thickness of the substrate from its back side, forming a first trench and a second trench extending through the substrate, the first trench exposing a bottom surface of a source/drain feature of the first plurality of transistors, the second trench exposing a bottom surface of a source/drain feature of the second plurality of transistors, forming a silicide layer in the first trench and the second trench, and forming a first source/drain contact in the first trench and a second source/drain contact in the second trench, wherein the power delivery network is disposed immediately under the first source/drain contact and the second source/drain contact. In some embodiments, the forming of the power delivery network may include depositing a first dielectric layer, forming first metal lines and first vias in the first dielectric layer and in the second region, depositing a second dielectric layer under the first dielectric layer, forming second metal lines and second vias in the second dielectric layer and in the second region, depositing a third dielectric layer under the second dielectric layer, forming third metal lines and third vias in the third dielectric layer and in the second region, forming an opening extending through the first dielectric layer, the second dielectric layer, and the third dielectric layer, wherein the opening is formed in the first region, and forming a conductive via in the opening, wherein the first portion of the power delivery network may include the conductive via, and the second portion of the power delivery network may include the first metal lines and first vias, the second metal lines and second vias, and the third metal lines and third vias. In some embodiments, a diameter of the conductive via may be greater than a diameter of a via of a second portion of the power delivery network. In some embodiments, the forming of the power delivery network may include depositing an insulation layer under the conductive via, forming a metal line opening extending through the insulation layer to expose a bottom surface of the conductive via, and forming a metal line in the metal line opening.

In yet another exemplary aspect, the present disclosure is directed to a semiconductor structure. The semiconductor structure includes a first transistor comprising a plurality of nanostructures, a gate structure wrapping around each of the plurality of nanostructures, and first and second source/drain features coupled to each of the plurality of nanostructures. The semiconductor structure also includes a first source/drain contact disposed under the first source/drain feature, a first metal line in a first dielectric layer and electrically coupled to the first source/drain contact, the first metal line being disposed under and in direct contact with the first source/drain contact, a multi-layer dielectric structure disposed under first dielectric layer, a first via extending through the multi-layer dielectric structure and in direct contact with the first metal line, and a second metal line in a second dielectric layer and in direct contact with the first via, the second dielectric layer being disposed under the multi-layer dielectric structure.

In some embodiments, the semiconductor structure may also include a second source/drain contact disposed over the second source/drain feature, and a multi-layer interconnect structure disposed over the second source/drain contact. The semiconductor structure may also include a multi-layer interconnect structure disposed under the first source/drain contact and comprising a plurality of metal lines and a plurality of conductive vias, wherein the multi-layer dielectric structure is a part of the multi-layer interconnect structure. In some embodiments, a thickness of the first via is greater than a thickness of the first metal line.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a workpiece comprising a first transistor and a second transistor formed over a first side of a substrate;
forming a first multi-layer interconnect structure over the first side of the substrate, wherein the first multi-layer interconnect structure comprising a first plurality of metal lines and a first plurality of vias;
after the forming of the first multi-layer interconnect structure, forming a source/drain contact directly under a source/drain feature of the first transistor; and
forming a second multi-layer interconnect structure under the source/drain contact and under a second side of the substrate, the second side being opposite the first side, wherein the second multi-layer interconnect structure comprises a second plurality of metal lines and a second via,
wherein a thickness of the second via is greater than a thickness of a via of the first plurality of vias.

2. The method of claim 1, wherein the via of the first plurality of vias spans a first width, the second via spans a second width, a ratio of the second width to the first width is greater than 10.

3. The method of claim 1, wherein the second via is disposed vertically between and in direct contact with two metal lines of the second plurality of metal lines, and one of the two metal lines of the second plurality of metal lines is in direct contact with the source/drain contact.

4. The method of claim 1, wherein the forming of the second multi-layer interconnect structure comprises:
depositing a first dielectric layer under the second side of the substrate;
forming a first trench in the first dielectric layer to expose a bottom surface of the source/drain contact;
forming one of the second plurality of metal lines in the first trench;
depositing a second dielectric layer under the first dielectric layer;
depositing a third dielectric layer under the second dielectric layer;
forming a second trench extending through the second and third dielectric layers, the second trench exposing a portion of the one of the second plurality of metal lines;
forming the second via in the second trench; and
forming another one of the second plurality of metal lines under the second via.

5. The method of claim 4, wherein the forming of the second via comprises:
forming a barrier layer in the second trench;
forming a conductive material to fill a remaining part of the second trench; and
performing a planarization process to remove portions of the barrier layer and conductive material disposed under the third dielectric layer.

6. The method of claim 1, further comprising:
after the forming of the second multi-layer interconnect structure, forming a conductive pad under and in direct contact with the second via; and
forming a solder bump under the conductive pad.

7. The method of claim 1, wherein the second transistor comprises:
a plurality of nanostructures disposed over the substrate;
a gate structure wrapping around and over each of the plurality of nanostructures; and
a source feature and a drain feature coupled to the plurality of nanostructures.

8. The method of claim 1, wherein the forming of the source/drain contact comprises:
reducing a thickness of the substrate;
forming an opening extending through the substrate to expose a bottom surface of the source/drain feature;
forming a dielectric liner extending along sidewall surface of the opening;
forming a silicide layer in the opening and in direct contact with the source/drain feature; and
depositing a conductive material in the opening.

9. The method of claim 1, further comprising:
before the forming of the first multi-layer interconnect structure, forming source/drain contacts and gate vias over the first side of the substrate.

10. The method of claim 1, wherein the thickness of the second via is greater than a thickness of a metal line of the second plurality of metal lines.

11. A method, comprising:
receiving a workpiece comprising a first plurality of transistors in a first region and a second plurality of transistors in a second region over a substrate; and
forming a power delivery network under the substrate to provide power signals to the first plurality of transistors and the second plurality of transistors, wherein the power delivery network comprises a first portion having a first number of conductive features electrically coupled to the first plurality of transistors and a second portion having a second number of conductive features electrically coupled to the second plurality of transistors,
wherein the first number is less than the second number.

12. The method of claim 11, further comprising:
before the forming of the power delivery network, forming gate vias over and electrically coupled to gate structures of the first plurality of transistors and the second plurality of transistors;
forming source/drain contacts over and electrically coupled to source/drain features of the first plurality of transistors and the second plurality of transistors by way of silicide layers; and
forming an interconnect structure over the workpiece, the interconnect structure comprising metal lines and vias embedded in dielectric layers and over the gate vias and the source/drain contacts.

13. The method of claim 11, further comprising:
before the forming of the power delivery network, thinning down a thickness of the substrate from its back side;
forming a first trench and a second trench extending through the substrate, the first trench exposing a bottom surface of a source/drain feature of the first plurality of transistors, the second trench exposing a bottom surface of a source/drain feature of the second plurality of transistors;
forming a silicide layer in the first trench and the second trench; and
forming a first source/drain contact in the first trench and a second source/drain contact in the second trench,
wherein the power delivery network is disposed immediately under the first source/drain contact and the second source/drain contact.

14. The method of claim 11, wherein the forming of the power delivery network comprises:
depositing a first dielectric layer;
forming first metal lines and first vias in the first dielectric layer and in the second region;
depositing a second dielectric layer under the first dielectric layer;
forming second metal lines and second vias in the second dielectric layer and in the second region;
depositing a third dielectric layer under the second dielectric layer;
forming third metal lines and third vias in the third dielectric layer and in the second region;
forming an opening extending through the first dielectric layer, the second dielectric layer, and the third dielectric layer, wherein the opening is formed in the first region; and
forming a conductive via in the opening,
wherein the first portion of the power delivery network comprises the conductive via, and the second portion of the power delivery network comprises the first metal lines and first vias, the second metal lines and second vias, and the third metal lines and third vias.

15. The method of claim 14, wherein a diameter of the conductive via is greater than a diameter of a via of a second portion of the power delivery network.

16. The method of claim 14, wherein the forming of the power delivery network further comprises:
depositing an insulation layer under the conductive via;
forming a metal line opening extending through the insulation layer to expose a bottom surface of the conductive via; and
forming a metal line in the metal line opening.

17. A semiconductor structure, comprising:
a first transistor comprising:
a plurality of nanostructures,
a gate structure wrapping around each of the plurality of nanostructures, and,
first and second source/drain features coupled to each of the plurality of nanostructures;
a first source/drain contact disposed under the first source/drain feature;
a first metal line in a first dielectric layer and electrically coupled to the first source/drain contact, the first metal line being disposed under and in direct contact with the first source/drain contact;
a multi-layer dielectric structure disposed under first dielectric layer;
a first via extending through the multi-layer dielectric structure and in direct contact with the first metal line; and
a second metal line in a second dielectric layer and in direct contact with the first via, the second dielectric layer being disposed under the multi-layer dielectric structure.

18. The semiconductor structure of claim 17, further comprising:
a second source/drain contact disposed over the second source/drain feature; and
a multi-layer interconnect structure disposed over the second source/drain contact.

19. The semiconductor structure of claim 17, further comprising:
a multi-layer interconnect structure disposed under the first source/drain contact and comprising a plurality of metal lines and a plurality of conductive vias, wherein the multi-layer dielectric structure is a part of the multi-layer interconnect structure.

20. The semiconductor structure of claim 17, wherein a thickness of the first via is greater than a thickness of the first metal line.
